(19) United States
(12) Patent Application Publication
(10) Pub. No.: US 2003/0221817 A1
(43) Pub. Date: Dec. 4, 2003

(54) Rack mountable computer component cooling method and device

(75) Inventors: John V. Smith, Poway, CA (US); Victor P. Hester, El Cajon, CA (US); William A. Wylie, San Diego, CA (US)

Correspondence Address: DUCKOR SPRADLING METZGER, 401 WEST A STREET, SUITE 2400, SAN DIEGO, CA, 92101-7915, US

(73) Assignee: RackSaver, Inc.

(21) Appl. No.: 10/448,691

(22) Filed: May 29, 2003

Related U.S. Application Data
(60) Provisional application No. 60/384,996, filed on May 31, 2002.
(60) Provisional application No. 60/384,987, filed on May 31, 2002.
(60) Provisional application No. 60/384,986, filed on May 31, 2002.
(60) Provisional application No. 60/385,005, filed on May 31, 2002.

(51) Int. Cl. H05K 7/20

(52) U.S. Cl. 165/80.3; 165/185; 174/16.3

(57) ABSTRACT

According to at least one of the disclosed embodiments of the present invention, there is provided a method and apparatus for mounting heat sinks for a rack mounted computer component. The heat sink is adapted to be mounted on a vertically mounted computer component blade where the heat sink is disposed such that vertical air flow provides sufficient contact with the heat sink fins for efficient and rapid cooling purposes.

### RELATED APPLICATIONS

This application claims priority to the following U.S. provisional applications: Serial No. 60/384,996, titled “Rack Mountable Computer Component and Method of Making Same”, filed May 31, 2002; Serial No. 60/384,987, titled “Rack Mountable Computer Component Cooling Method and Device”, filed May 31, 2002; Serial No. 60/384,986, titled “Rack Mountable Computer Component Fan Cooling Arrangement and Method”, and Serial No. 60/385,005, titled “Rack Mountable Computer Component Power Distribution Unit and Method”, which are each hereby incorporated by reference in their entirety.

This application relates to the following U.S. non-provisional patent applications: Attorney Docket No. 7719-110, titled “Rack Mountable Computer Component and Method of Making Same,” filed May 28, 2003; Attorney Docket No. 7719-112, titled “Rack Mountable Computer Component Fan Cooling Arrangement and Method”; and Attorney Docket No. 7719-113, titled “Rack Mountable Component Power Distribution Unit and Method,” which are each hereby incorporated by reference in their entirety.

### BACKGROUND OF THE INVENTION

1. Field of the Invention

The present invention relates in general to a new and improved method and computer components adapted for rack mounting. It more particularly relates to such a method and apparatus for cooling computer components adapted to be mounted in a compact configuration.

2. Related Art

There have been a variety of different types and kinds of methods and systems for mounting computer components. For example, reference may be made to the following United States patents:

| PATENT NO. | INVENTOR | ISSUE DATE |
|---|---|---|
| 4,258,967 | Boudreau | Mar. 31, 1081 |
| 4,879,634 | Storrow et al. | Nov. 07, 1989 |
| 4,977,532 | Borkowicz et al. | Dec. 11, 1990 |
| 5,010,444 | Storrow et al. | Apr. 23, 1991 |
| 5,216,579 | Basara et al. | Jun. 01, 1993 |
| 5,460,441 | Hastings et al. | Oct. 24, 1995 |
| 5,571,256 | Good et al. | Nov. 05, 1996 |
| 5,684,671 | Hobbs et al. | Nov. 04, 1997 |
| 5,877,938 | Hobbs et al. | Mar. 02, 1999 |
| 5,896,273 | Varghese et al. | Apr. 30, 1999 |
| 6,025,989 | Ayd et al. | Feb. 15, 2000 |
| 6,058,025 | Ecker et al. | May. 02, 2000 |
| 6,075,698 | Hogan et al. | Jun. 13, 2000 |
| 6,220,456 B1 | Jensen et al. | Apr. 24, 2001 |
| 6,305,556 B1 | Mayer | Oct. 23, 2001 |
| 6,315,249 B1 | Jensen et al. | Nov. 13, 2001 |
| 6,325,636 B1 | Hipp et al. | Dec. 04, 2001 |
| Re. 35,915 | Hastings et at. | Oct. 06, 1998 |
| Des. 407,358 | Belanger et al. | Mar. 30, 1999 |

As a result of having available a large number of different types and kinds of mounting techniques, a standard has been adopted for mounting computer components in racks according to a certain modular configuration. In this regard, computer components such as computer processor units, and the like, are mounted one above the other in a column in standard size rack configurations. The standard is referred to as the EIA-310-D Standard, as clarified by the Server Rack Specification (SSI).

The housing for each computer device must have a certain height dimensions according to the Standard. The height dimension must be a multiple of a standard unit “U”. Thus, there can be computer components which are 1 “U” (standard unit) high or multiples thereof. Thus, there can also be standard rack mountable computer components which are 1 U, 2 U, 3 U, 4 U and so on.

Thus, according to the conventional currently-used standard, racks are provided for storage of computer components in tightly spaced, densely packed horizontal dispositions, and each computer component mounted in the rack is suitably dimensioned in multiples of standard unit U. The racks are movably mounted on casters or the like so that they can be readily positioned in, for example, a computer room having a tightly controlled air conditioning system to ensure proper cooling of the computer equipment.

It is highly desirable to configure the computer components in the rack in a compact and highly dense manner for some applications. Thus, it has been important for many applications to position in the computer room or other assigned space as many computer components as possible.

In order to compactly mount the computer components on the rack in a high density manner, they are closely positioned one above the other in a column. The data and power cables are positioned in a back plane area or space within the rack.

For cooling purposes, various techniques are employed. For example, individual fans have been mounted within the housing of each computer component. The interiors of the housing have been exhausted to a fan exhaust plenum chamber often times constructed within the rack at one side thereof.

Such conventional rack mounted systems have several drawbacks. The individual fans mounted in each component are expensive, and time-consuming to replace in case of malfunctions. Also, the back plane space and fan exhaust plenum chamber are wasted space in that they occupy spaces which could otherwise be filled with computer components.

Additionally, in order to assemble the rack mounted system for installation at the site, each component must be installed in place within the rack, and then the cabling for each unit is routed within the rack at its back plane space. Such an operation is time consuming, and therefore expensive since highly trained personnel are required to do such an installation. Furthermore, once installed, in order to replace a malfunctioning computer component, the entire system, or at least a substantial portion thereof, must be shut down so that the malfunctioning unit can be disassembled, and a replacement unit installed and reconnected electrically. This, too, is time consuming and expensive.

In conventional rack mounted computer components, the circuits within the component housing are cooled by providing intake fans to draw air into the housing through the front portion thereof. There are also exhaust fans typically mounted on the side of the housing to exhaust the heated air from within the computer component housing. For cooling purposes, heat sinks are mounted on circuit components such as microprocessor chips to help dissipate heat build-up therein. The moving air then transfers the heat from the heat sink and is exhausted outside of the component housing.

Since the air enters the front of the housing and exits the interior thereof at a side of the housing, the path of travel of the air is irregular, and thus the placement of the heat sink in the air flow path can be difficult. In this regard, it may be required to employ baffles or the like to direct the air flow through the spaced-apart fins on the heat sink.

### BRIEF DESCRIPTION OF THE DRAWINGS

The following is a brief description of the drawings:

FIG. 1 is a pictorial view of a rack-mounted system showing the front, left side and top thereof, which is constructed in accordance with an embodiment of the present invention;

FIG. 2 is a front elevational view of the rack-mounted system of FIG. 1;

FIG. 3 is a left side elevational view of the rack-mounted system of FIG. 1;

FIG. 4 is a rear elevational view of the rack-mounted system of FIG. 1;

FIG. 5 is a right side elevational view of the rack-mounted system of FIG. 1;

FIG. 6 is a pictorial view of the rack-mounted system of FIG. 1, showing the rear, right side and top thereof;

FIG. 7 is a pictorial view of the housing of the rack-mounted system of FIG. 1 without various components being mounted for illustration purposes;

FIG. 8 is a pictorial view of the housing of FIG. 7 illustrating the process of installation of fan/LAN trays;

FIG. 9 is an enlarged scale pictorial view of one embodiment of a fan/LAN tray for the rack-mounted system of FIG. 1;

FIG. 10 is a pictorial view of the housing of FIG. 7 with the fan/LAN trays installed;

FIG. 11 is a pictorial view of the housing of FIG. 7 illustrating the process of installation of blades;

FIG. 12 is a fragmentary, enlarged scale front elevational view of the rack-mounted system of FIG. 1 illustrating the relative positioning of the fan/LAN trays and the blades;

FIG. 13 is a diagrammatic, right-side elevational view of the rack-mounted system of FIG. 1 illustrating the configuration of the right-side cabling;

FIG. 14 is a bottom fragmentary pictorial view of the rack-mounted system of FIG. 1 illustrating the cabling in the front and right portion of the control bay;

FIG. 15 is a diagrammatic, left-side elevational view of the rack-mounted system of FIG. 1 illustrating the configuration of the left-side cabling;

FIG. 16 is a bottom fragmentary pictorial view of the rack-mounted system of FIG. 1 illustrating the cabling in the rear and left portion of the control bay;

FIG. 17 is an enlarged scale, fragmentary pictorial view of one embodiment of a power distribution unit (PDU) for the rack-mounted system of FIG. 1;

FIG. 18 is a front elevational view of the PDU shown in FIG. 17;

FIG. 19 is a fragmentary top view of the PDU shown in FIG. 17;

FIG. 20 is a rear elevational view of the PDU shown in FIG. 17;

FIG. 21 is a diagrammatic view of the rack-mounted system of FIG. 1 illustrating the flow of air therethrough;

FIG. 22 is a diagrammatic view of another embodiment of a rack-mounted system according to the present invention and illustrating the flow of air therethrough;

FIG. 23 is a diagrammatic view of yet another embodiment of a rack-mounted system according to the present invention and illustrating the flow of air therethrough;

FIG. 24 is a diagrammatic view of still another embodiment of a rack-mounted system according to the present invention and illustrating the flow of air therethrough;

FIG. 25 is an enlarged scale top view of one embodiment of a blade of the rack-mounted system of FIG. 1;

FIG. 26 is a left side elevational view of the blade of FIG. 29;

FIG. 27 is an enlarged scale top view of a heat sink of the blade of FIG. 25, illustrating it rotated through 90°;

FIG. 28 is a side elevational view of the heat sink of FIG. 27;

FIG. 29 is a bottom view of the heat sink of FIG. 27;

FIG. 30 is a top view of another heat sink which may also be used with the computer blade of FIG. 25 in accordance with another embodiment of the present invention;

FIG. 31 is a side elevational view of the heat sink of FIG. 30; and

FIG. 32 is a side elevational view of the heat sink of FIG. 30.

### DESCRIPTION OF CERTAIN EMBODIMENTS OF THE INVENTION

According to at least one of the disclosed embodiments of the present invention, there is provided a method and apparatus for mounting heat sinks for a rack mounted computer component. The heat sink is adapted to be mounted on a vertically mounted computer component blade where the heat sink is disposed such that vertical air flow provides sufficient contact with the heat sink fins for efficient and rapid cooling purposes.

According to the disclosed embodiments of the present invention, a heat sink is employed for an active component such as a microprocessor forming a part of a computer motherboard mounted on an upright support. The heat sink includes a base portion having a series of spaced apart fins extending therefrom to provide a relatively large surface area to dissipate heat therefrom as substantially vertically flowing cooling air passes bewteen the fins. The base portion is mounted in a generally upright position with its fins extending in a generally upright position as well. According to at least one of the embodiments of the present invention, the ratio of the height of the fins to the height of the base portion is greater than seven.

According to other disclosed embodiments of the invention, the ratio of the height of the fins to the height of the base portion of the heat sink is between about 7.5 and about 10.45. Additionally, as disclosed herein, a heat conducting slug plate overlies the base portion, and is interposed between the base portion and the active component to be cooled.

According to the disclosed embodiments of the invention, there is disclosed a method of utilizing a heat sink to help cool an active component. The method includes the mounting of a support in a generally upright manner, and mounting the active component on one side of the support. The heat sink is mounted on the active component in a generally upright manner with the heat sink having spaced-apart fins extending from a base portion in a generally upright manner. A slug plate is interposed between the base portion and the active component to be cooled.

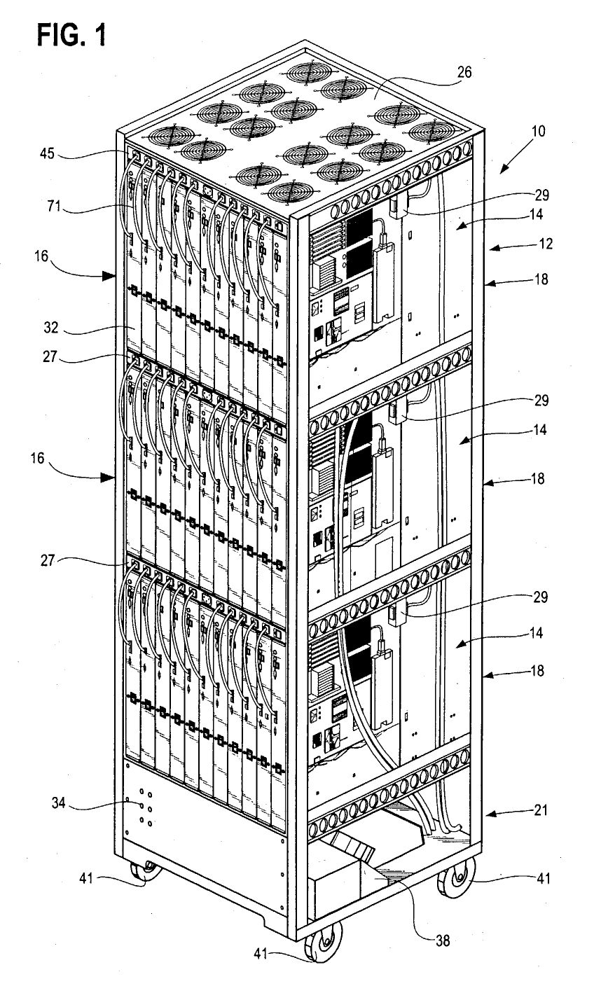

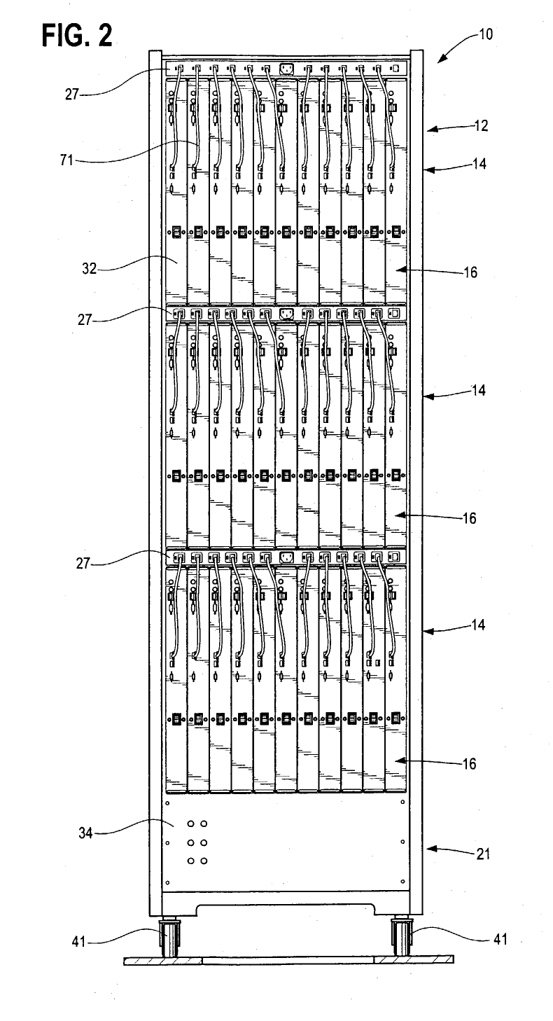

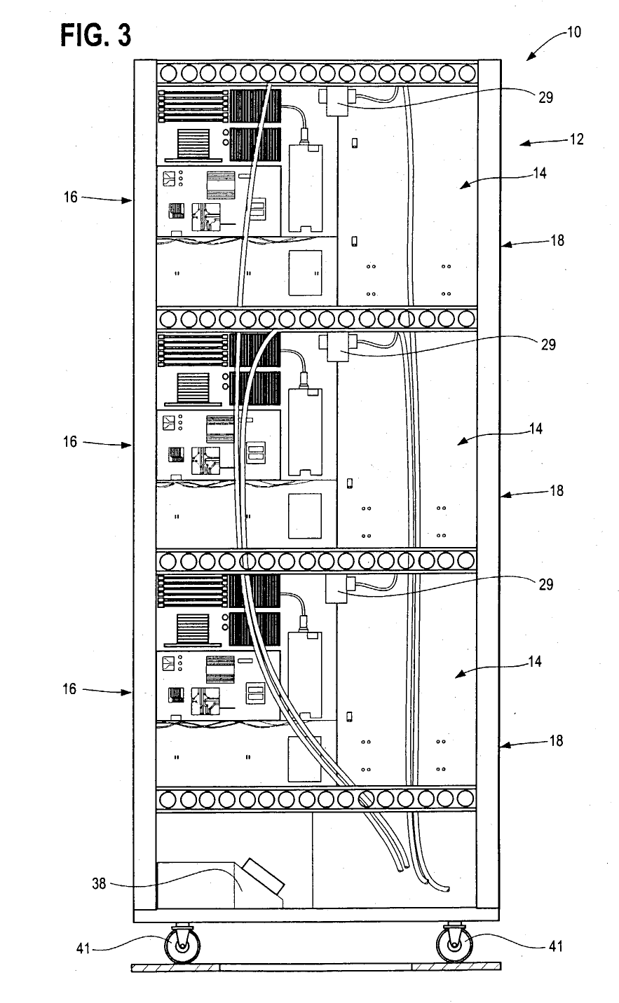

Referring now to the drawings, and more particularly to FIGS. 1 through 21 and 29 and 30, there is illustrated one embodiment of a rack mounted system 10 according to the present invention. The rack mounted system 10 includes a rack housing 12 configured generally as a rectangular box having a plurality of vertical bays 14. The embodiment illustrated in the drawings includes three vertically spaced-apart bays 14.

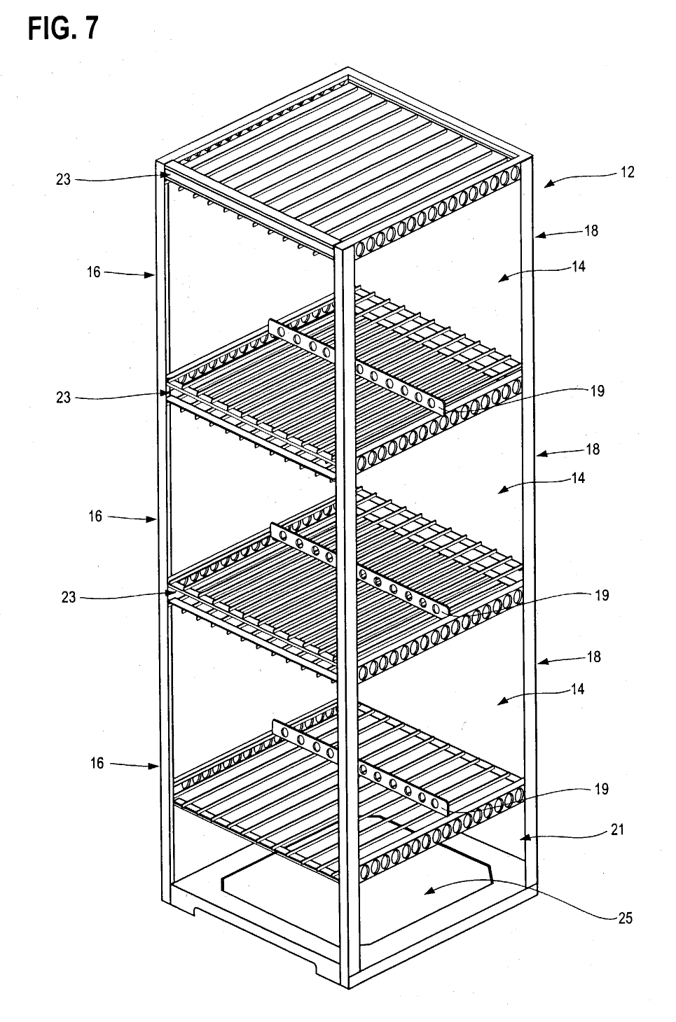

Each bay 14 is divided into a front bay portion 16 and a rear bay portion 18 by an intermediate transversely-extending horizontal divider 19. The intermediate divider 19 is most clearly illustrated in FIG. 7. The bays 14 are formed in the rack housing 12 in a vertical manner one above the other. In a bottom portion of the rack housing 12, a control bay 21 is provided to house various controlled components, as hereinafter described in greater detail.

The rack housing 12 further includes a fan/LAN tray slot 23 above each bay 14. Each fan/LAN tray slot is configured to accommodate a fan/LAN tray such as tray 27.

The embodiment illustrated in the drawings provides a control bay 21 (FIG. 7) having a bottom opening 25 (FIG. 7) for facilitating air flow to receive vertically moving air flow from a vent opening 26 in a floor 28 and vertically through the system 10 as assisted by the fan/LAN trays. At the top of the rack housing 12, an apertured top panel 26 (FIG. 1) is provided to permit venting of the vertically moving air flow from the system 10.

At the top portion of each bay 14, in the intermediate region between the front bay portion 16 and the rear bay portion 18, as best seen in FIGS. 1, 5, 6 and 8, a power distribution unit (PDU) 29 is provided to supply electricity to various components mounted in the rack mounted system. Each bay is adapted to accommodate a plurality of computer components in the form of open structure computer components or blades, such as blade 32 (FIG. 1), in each of the front bay portions 16 and the rear bay portions 18. In the embodiment illustrated in the figures, eleven blades may be accommodated in each of the front bay and rear bay portions in a generally upright disposition. Thus, in the illustrated embodiment, the system 10 accommodates 66 computer components in a densely compact, closely spaced configuration.

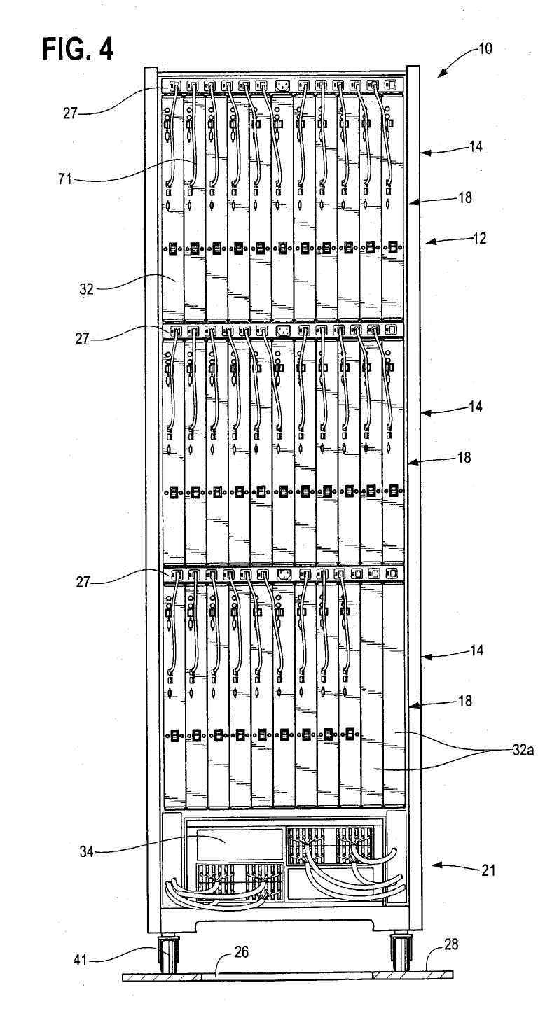

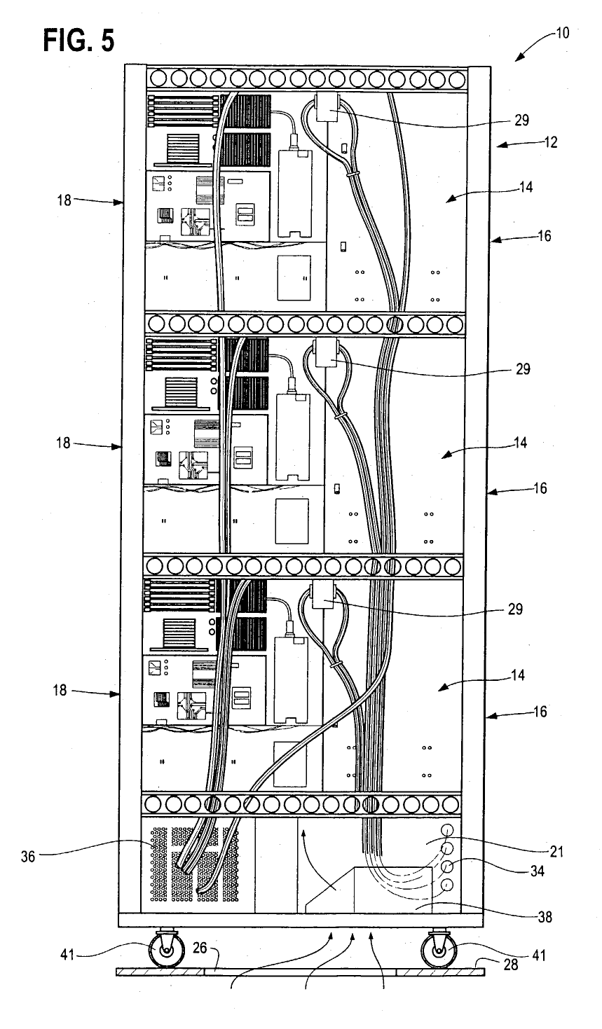

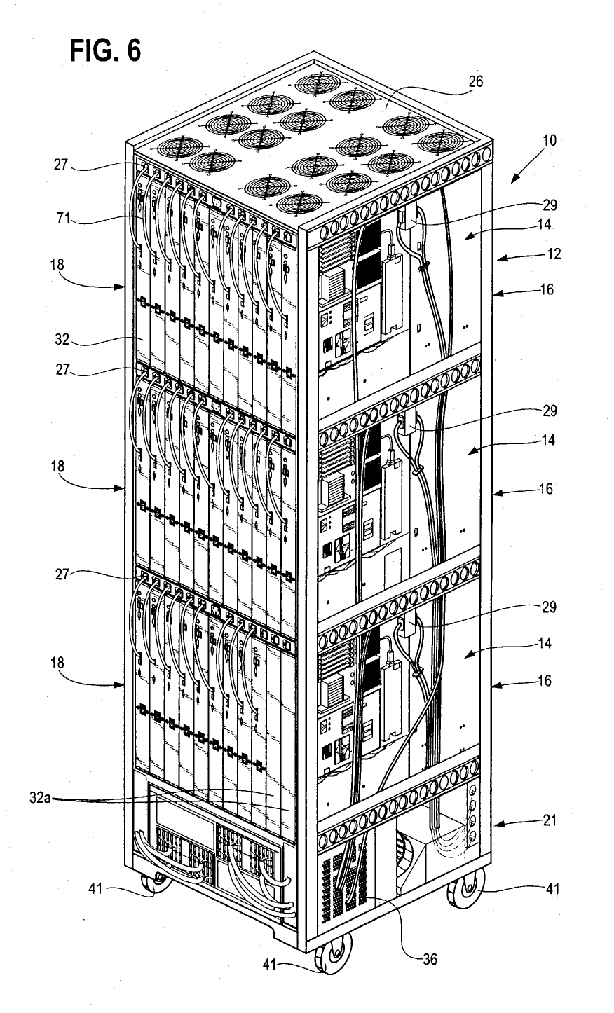

The bottom control bay 21 is adapted to accommodate various control components. These control components may include a circuit breaker junction box 34, as most clearly illustrated in FIG. 6. The circuit breaker junction box 34 is electrically connected to each PDU. As shown in FIG. 4, a switch module 36 is also provided in the control bay 21. The switch module 36 is adapted to control communication between the various blades, such as blade 32, and a network, such as a local area network, wide area network, or a public network, such as the internet. Further, the control bay 21 accommodates an air intake fan module 38 (FIGS. 1 and 5) for facilitating intake of air through the bottom opening 25 and facilitating vertical air flow through the blades and the bays 14 and out the apertured top panel 26.

The embodiment of the rack system 10 illustrated in the figures includes four casters 41 for rollably supporting the system on the floor 26 (FIG. 5) for easy portability of the rack system 10. Other embodiments of the rack system according to the present invention may be floor mounted, thereby including legs or skids in place of the casters for direct mounting to the floor.

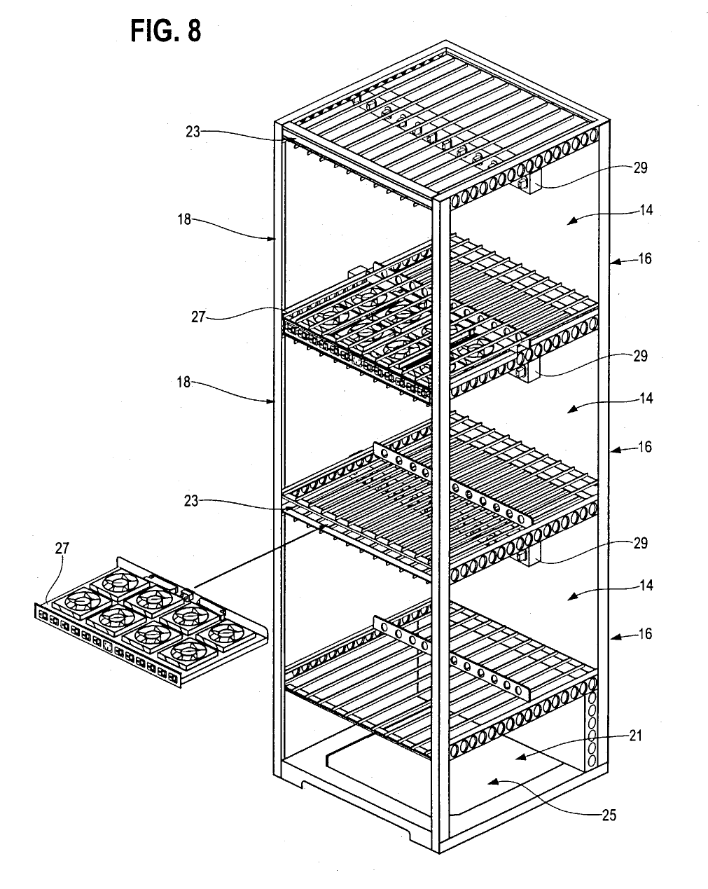

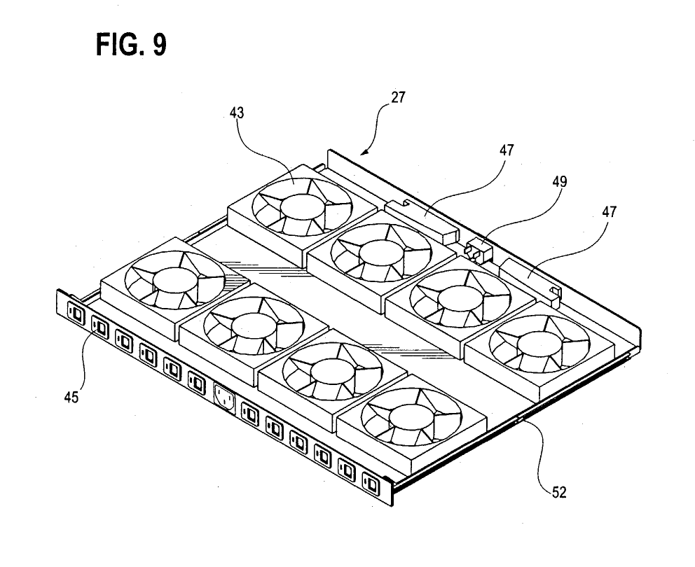

Referring now to FIGS. 8 and 9, the fan/LAN tray 27 and its installation into the rack housing 12 will be described in further detail. FIG. 9 illustrates one embodiment of a fan/LAN tray 27 for use with the rack system 10 illustrated in the drawings. The fan/LAN tray 27 includes eight suitable fans for facilitating vertical air flow. Although the embodiment illustrated in the drawings includes eight fans per tray, any suitable number of fans may be used.

In accordance with the disclosed embodiments of the present invention, the fan tray may also be divided into a plurality of separate trays or tray portions, each of which can be removed independently so that the remaining tray portion can continue to function. In this regard, it is contemplated that the LAN connections may be made in a unit or component separate from the fan tray or tray portions so that the tray or tray portion may be removed independently of the LAN component. In the front portion of the fan/LAN tray 27, a series of LAN connector ports 45 (FIGS. 1 and 9) is provided. In the embodiment illustrated in FIG. 9, each fan/LAN tray 27 includes 12 LAN connector ports 45, the end one of which may be used for test purposes. While 12 LAN connectors are shown in the disclosed embodiment, it should be understood that any number of such connectors may be employed for a given application. Internal wiring leads (not shown) from each LAN connector port 45 extend to one of two signal connectors 47 (FIG. 9) in the back portion of the fan/LAN tray 27. In one embodiment, each signal connector 47 is a 50 pin signal connector, and is connected electrically to the switch module 36. Further, each fan/LAN tray includes a AC power inlet 49 in the back portion for providing power to the fans. When installed, power may be supplied to the fans 43 through the AC power inlet 49 from the PDU 29, as hereinafter described in greater detail.

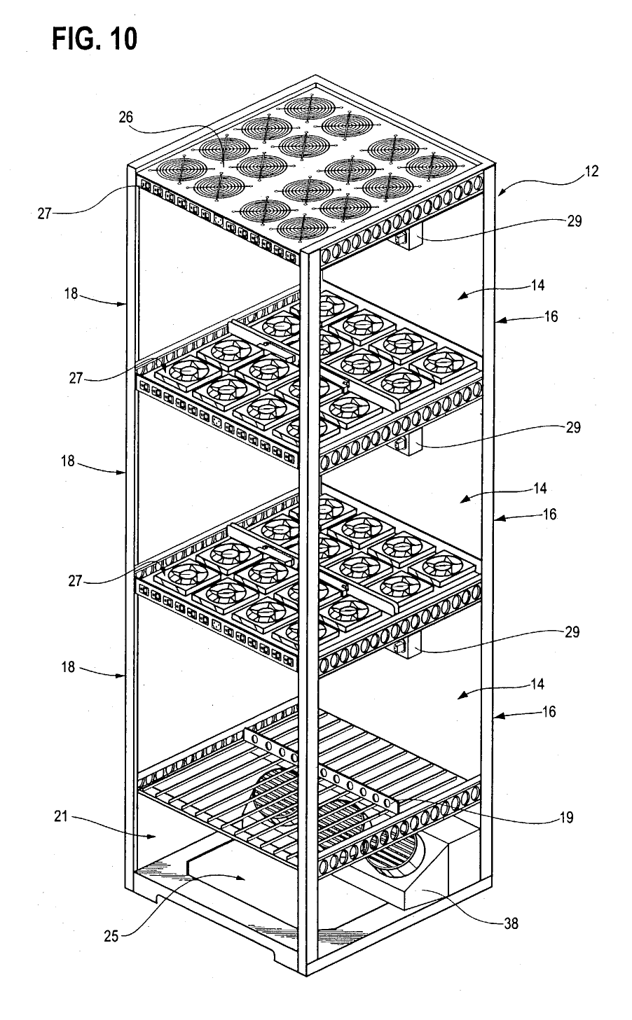

For facilitating installation of the fan/LAN tray 27 into the fan/LAN tray slot 23 of the rack housing 12, as shown in FIG. 9, guides 52 may be provided on the sides of each fan/LAN tray 27. During the installation process, the guides, preferably nylon guides, may engage corresponding member on the sides of the fan/LAN tray slots 23 to help support the fan/LAN tray. Further, a locking mechanism may be provided in conjunction with the guides 52 for securing the fan/LAN tray 27 into the fan/LAN tray slot 23. Once installed, each fan/LAN tray 27 occupies an area directly above either the front bay portion 16 or the rear bay portion 18. Accordingly, a fan/LAN tray in the front and a fan/LAN tray in the rear may completely cover each bay 14 level. Thus, as illustrated most clearly in FIG. 10, a total of 6 fan/LAN trays 27, in addition to the air intake fan module 38 may be provided in a three bay level rack mounted system 10 according to one embodiment of the present invention.

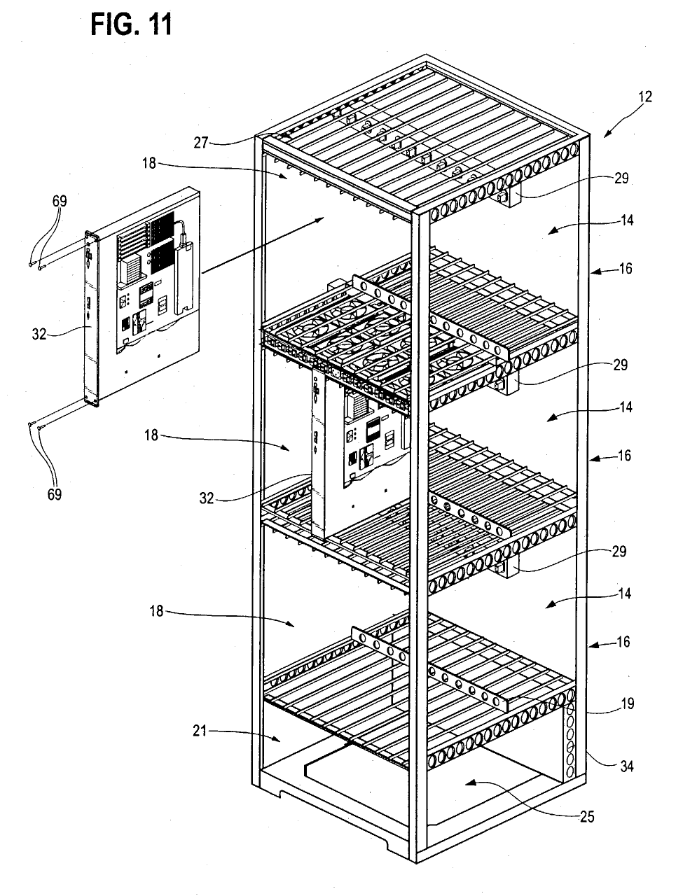

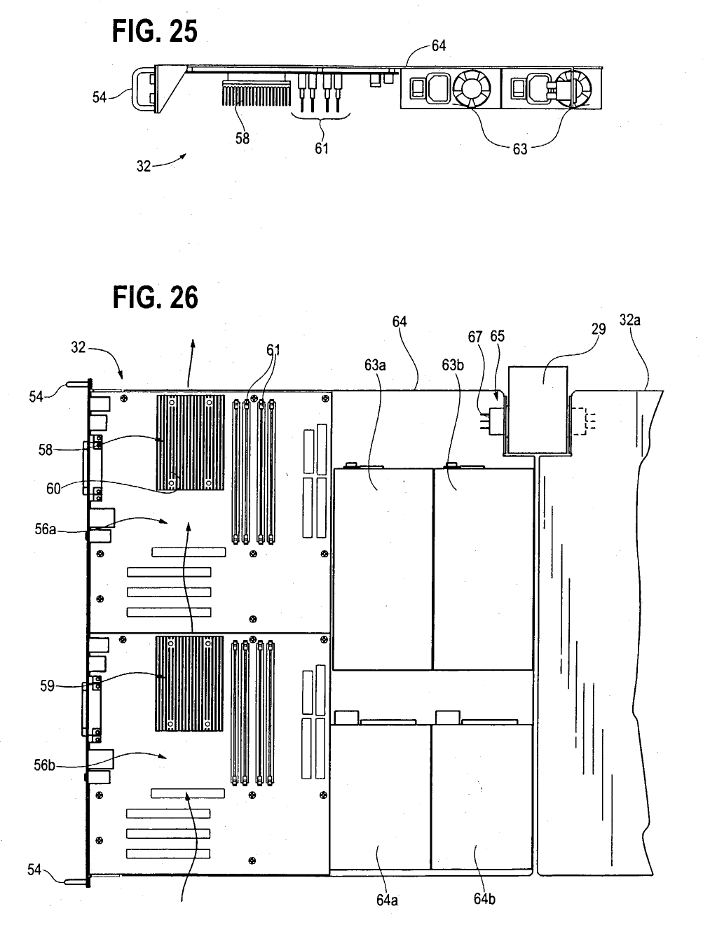

Referring now to FIGS. 11, 25 and 26, the blades 32 and their installation into the rack housing 12 will now be described in greater detail. Each blade is provided with a pair of handles 54 which allow a user to easily manipulate the blade 32 to be grasped by the user to slide the blade into or out of its bay. Each blade 32 may include one or more mother boards 56. In the embodiment illustrated in FIGS. 25 and 26, each blade 32 includes two mother boards 56a, 56b. Those skilled in the art will appreciate that the number of mother boards included in each blade 32 may be varied according to design. The mother board may include heat sinks such as heat sinks 58 and 59 for facilitating the cooling of the mother boards. Further, each mother board is provided with random access memory (RAM) 61. The amount of RAM 61 provided for each mother board may be varied as needed. A pair of power supply 63a, 63b may be provided on the blade 32 for supplying power to their corresponding mother boards 56a, 56b. Similarly, a pair of hard disks 64a, 64b may also be provided on the blade 32.

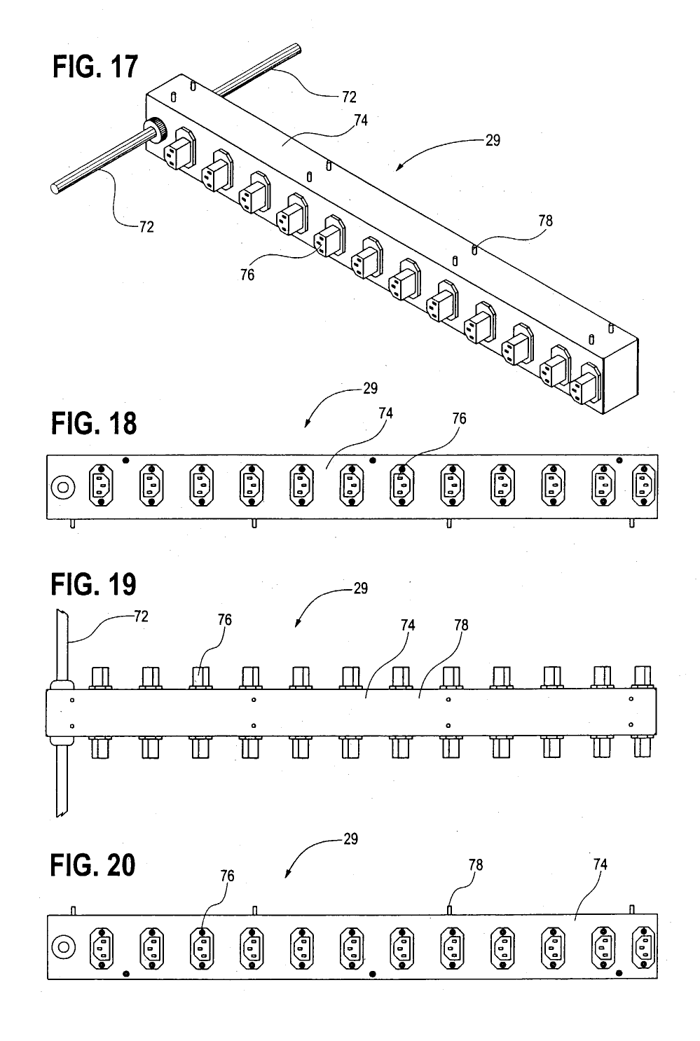

All of the components are mounted on one side of a rigid plate or support 64, which is adapted to be supported vertically within its bay. Each blade 32 includes a cut-out corner portion or section 65 in its upper back portion. The cut-out portion 65 is sized to receive and accommodate the PDU 29 therebetween such that two opposing blades 32 and 32a (as shown in FIG. 26) accommodate the PDU 29 almost completely. Thus, a substantially zero footprint is achieved for the PDU 29. Each blade 32 is provided with an AC power inlet such as an inlet 67 at or near the cut-out portion 65. Thus, when the blade 32 is installed into the rack housing 12, the AC power inlet 67 engages electrically a corresponding AC connector such as a connector 76 (FIG. 17) of the PDU 29.

As most clearly illustrated in FIG. 11, the installation of the blade 32 may be achieved in a fast and efficient manner. The blade 32 is simply slid into either the front bay portion 16 or the rear bay portion 18 of a bay 14 of the rack housing 12. Each blade 32 is slid back until its AC power inlet 67 engages a corresponding AC connector 76 on the PDU 29. The intermediate dividers 19 serve as a back stop for the blades 32. Each blade 32 is secured in its slot by four blade screws 69, which attach the blade 32 to the rack housing 12.

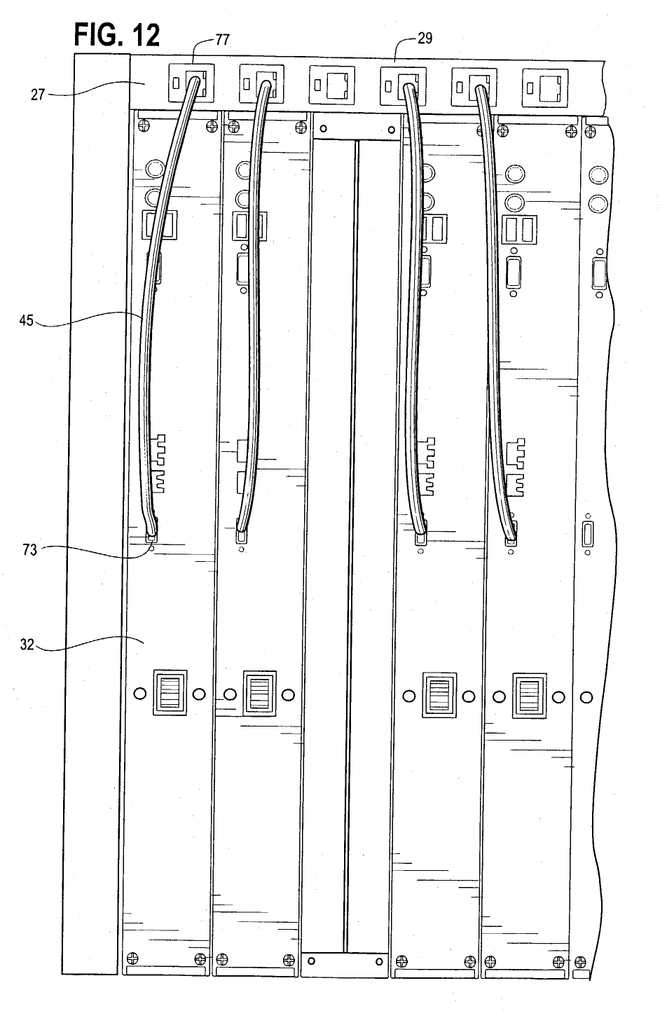

Once the blade 32 has been mounted onto the rack housing 12, a short blade/LAN connector cable such as a cable 45 (FIG. 12) or a cable 71 (FIG. 1) provides electrical networking connection between the blade 32 and a network such as a local area network, wide area network or a public network such as the internet. In this regard, the mother boards are each mounted at the front of each blade, and thus access thereto is readily available at front outlets such as at outlet 73 (FIG. 12). Thus, a data connection can be made from the outlet 73, through a short cable 45, an inlet 77 of a PDU 29, which is coupled to the switch module 36.

Referring now to FIGS. 17 through 20, the power distribution unit 29 will now be described in greater detail. The PDU 29 supplies power from an external power source, through the circuit breaker junction box 34, to the various blades 32 and the fan/LAN trays 27. Each PDU 29 includes an elongated PDU body 74, which preferably is formed of a two piece, 18 gauge steel chassis. Each of two sides of the PDU body 74 includes a series of female AC connectors 76. In the embodiment illustrated in FIGS. 17 through 20, each side is provided with 12 female AC connectors 76. The twelve connectors 76 correspond to eleven blades mounted in the front bay portion 16 and the rear bay portion 18 of each bay 14 and a fan/LAN tray 27. The twelfth connector is for an AC power outlet on the front of the fan tray.

Thus, 12 female AC connectors 76 are provided on each of a front side and a rear side of the PDU body 74. Each set of twelve female AC connectors 76 receives power through a pair of power cables 72. In one embodiment, the power cable 72 is a 15 amp power cable with strained relief near its junction with the PDU body 74. As described below, the power cables 72 are routed to the circuit breaker junction box 34 in the control bay 21. The PDU body 74 may also include a series of mounting studs 78 for installation of the PDU body 74 to the rack housing 12.

Referring now to FIGS. 13 through 16, the routing of the various power and LAN cables will now be described in detail. As illustrated most clearly in FIG. 13, the power cables 72 from the PDU's 29 at each bay level are directed along the right side of the rack housing 12 toward the front portion of the rack housing 12 and to the bottom, where they are connected electrically to the circuit breaker junction box 34. Thus, in the embodiment illustrated in the drawings, six power cables 72 are connected to the circuit breaker junction box 34, since there are two from each one of the three PDUs. A set of three cables generally indicated at 80 are each adapted to be coupled to a suitable source of AC power to supply power to the system 10.

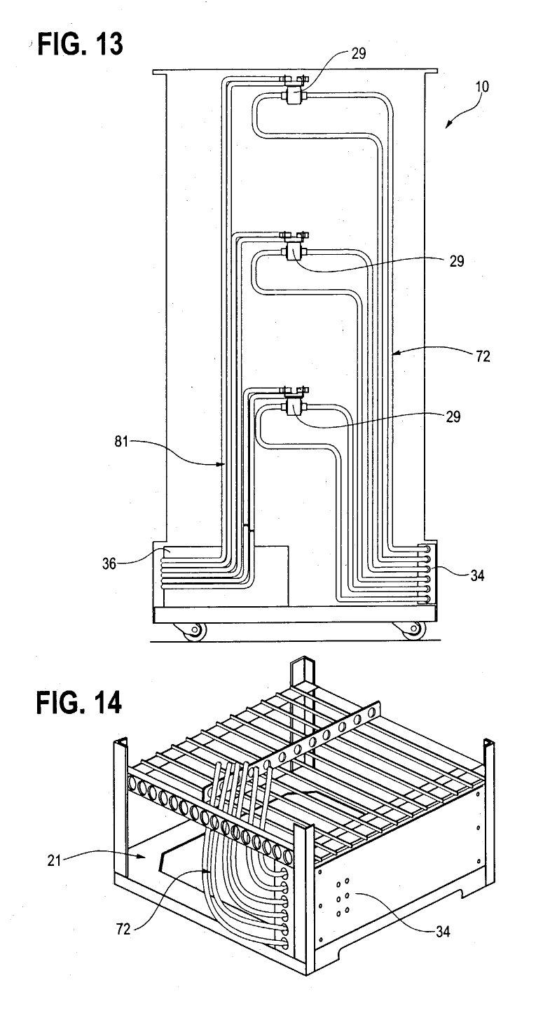

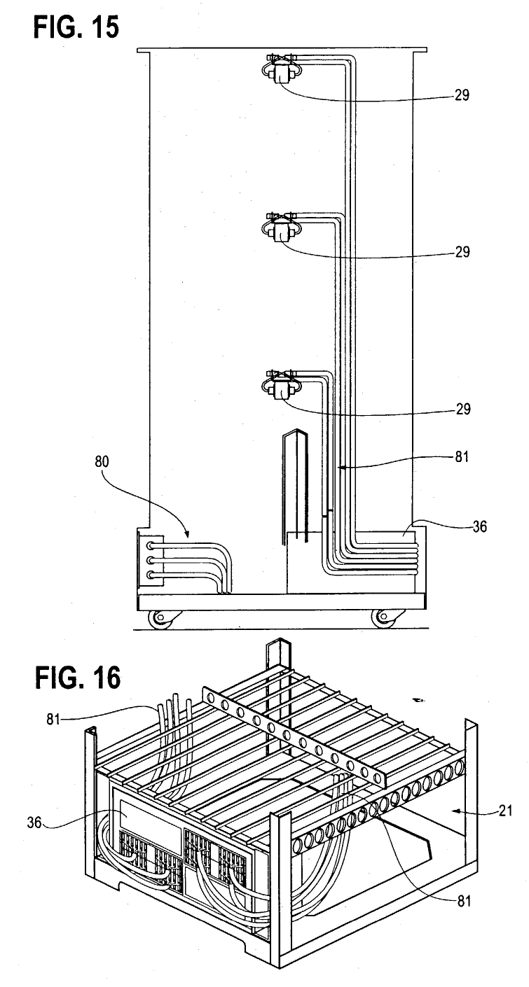

As also illustrated in FIG. 13, a set of six LAN cables 81 from the fan/LAN trays and PDUs are routed along the rear right side of the rack housing 12 to the switch module 36. In the embodiment illustrated in the drawings, two LAN cables 81 extend from each PDU which, in turn, are connected electrically to a pair of fifty pin signal connectors 47. Thus, six such cables 81 are directed along the right side of the rack housing 12. Similarly, as most clearly shown in FIG. 15, six LAN cables 81 extend from the fan/LAN trays 27 and PDUs along the left front side of the rack housing 12. These six cables 81 are also connected at their lower ends to the switch module 36.

Once the rack system 10 is fully assembled with all the fan/LAN trays 27, PDUs 29 and the blades 32 in place, a fully assembled and efficient rack mounted system is provided. In such a system, networking of the various components provided on the blades 32 is also performed efficiently. In the embodiment illustrated in the drawings, eleven blades are accommodated at each of the front bay portion 16 and the rear bay portion 18 at each bay 14. Thus, in the embodiment illustrated, 66 such blades 32 may be accommodated. However, some of the slots may be occupied by master computer components or blades such as the master blades indicated at 32a in FIGS. 4 and 6. In the illustrated embodiment, two master blades 32a are provided in the bottom of the three blade bays directly above the switch module 36. The master blades 32a are connected electrically directly to the switch module 36 via high speed connections (not shown) such as fiber optic connections. The master blades control the switch module 36 to switch communication between the various slave blades 32 and the master blades. Accordingly, 64 slave blades may be accommodated by the illustrated embodiment of the system. Each of the 64 slave blades may be hot swappable, for example, allowing replacement of the blades 32 without causing the shutting down of the system 10.

Each fan/LAN tray 27 is provided with twelve LAN connector ports such as the port 45 (FIG. 1). Eleven of the 12 LAN connector ports 45 are adapted to permit communication between the various slave blades 32 and the switch module 36. The twelfth LAN connector port 45 allows an external user to connect an external device such as a laptop computer to the network. Further, each fan/LAN tray 27 is provided with a centrally disposed AC power outlet for connecting such an external device.

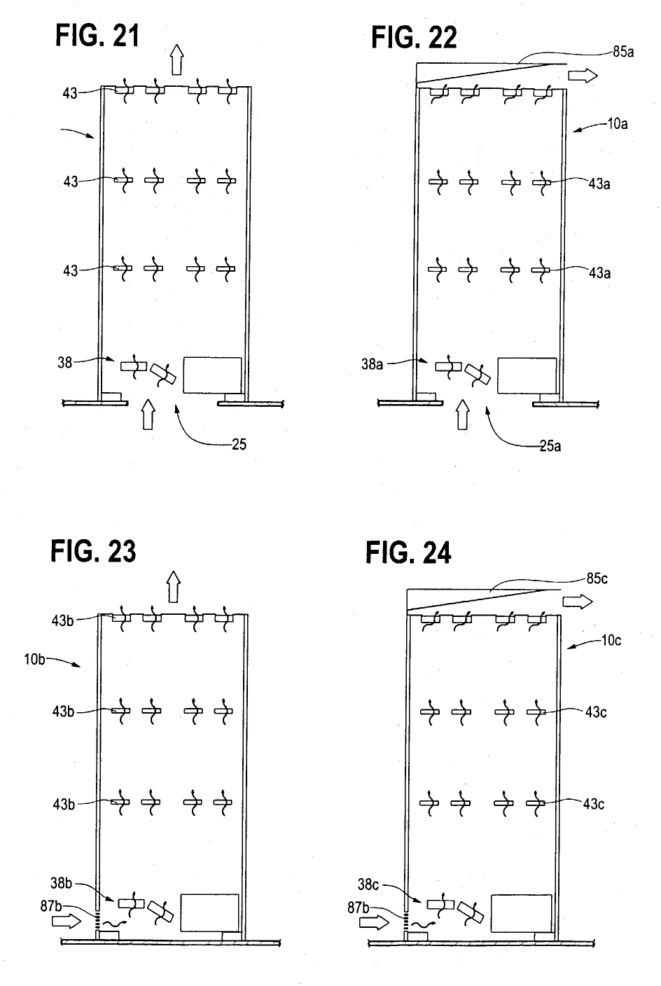

According to the disclosed embodiments of the present invention, and as indicated diagrammatically in FIG. 21, the system 10 illustrated in the figures provides efficient air flow to maintain a cool operating temperature for the various components mounted on the blades 32. Air flow is directed from the bottom opening 25 by the air intake fan module 38 located in the control bay 21. The air intake fan module 38 directs the air flow vertically through the various open structure blades 32 at each bay level 14. The air flow is further facilitated by the fans 43 in each fan/LAN tray 27 to move the air in its upwardly directed path of travel. The air flow is directed out of the rack housing 12 through the apertured top panel 26.

FIGS. 21 through 24 illustrate further embodiments of the present invention. As illustrated in FIGS. 21 through 24, the intake and exhaust of the air flow may be varied to accommodate various configurations as to the availability of air supply in the immediate environment. For example, in FIG. 22, an air intake fan module 38a draws air from a bottom opening 25a, similar to that illustrated in the embodiment shown in FIGS. 1 through 21. Air flow is directed vertically with the aid of fans 43a mounted on fan/LAN trays. However, unlike the previously described embodiment, in the embodiment illustrated in FIG. 22, the air flow is re-directed from a vertical path of travel at right angles to a horizontal path of travel out of the rack system 10a towards the rear of the rack housing. An air flow hood 85a facilitates the rearward re-direction of the air flow.

FIG. 23 illustrates yet another embodiment of the rack system according to the present invention. In this embodiment, an air intake fan module 38b draws air horizontally inwardly through an opening such as defined by a perforated plate 87b in the bottom front portion of the rack housing. The air flow is then re-directed upwardly with the aid of fans 43b mounted in fan/LAN trays. The air flow is directed vertically out of the top portion of rack system 10b.

In the embodiment illustrated in FIG. 24, an air intake fan module 38c draws air horizontally through an opening such as defined by a perforated plate 87c in the front bottom portion of the rack housing. The air flow is re-directed vertically through this system with the aid of fans 43c. The air flow is re-directed at right angles to a horizontal path of travel out of the rack housing rearwardly at the top of the rack housing. The rearward redirection of the air flow is facilitated by an airflow hood 85c. It will be appreciated by those skilled in the art that other variations on the intake and exhaust of the air flow are possible in accordance with other embodiments of the present invention.

Heat Sink Construction

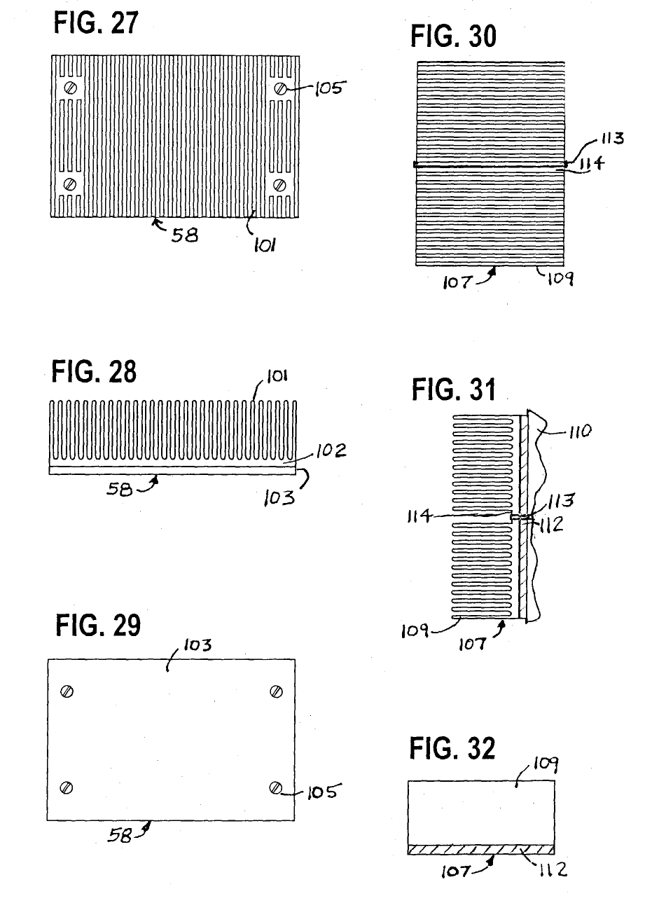

Referring now to FIGS. 27, 28 and 29, there is shown in greater detail the heat sink 58, which is a passive heat sink and which is adapted to be attached to a circuit component such as a microprocessor (not shown) for the mother board 56a (FIG. 26) to dissipate unwanted heat therefrom. The preferred orientation of the heat sink 58, when mounted on its mother board, is seen in FIG. 26. The heat sink 58 is generally composed of an aluminum alloy (6063-T5) or other suitable metallic material and includes a series of fins such as fin 101 extending from a base portion 102, to provide for a relatively large surface area to dissipate heat therefrom as the substantially vertical air flow passes therebetween. The heat sink 58 may be extruded. The heat sink 58 includes a base or slug plate 103, which is composed of suitable metallic material such as copper and which overlies the base portion 102 and is adapted to be attached to the component to be protected by any suitable technique such as by soldering. The metallic slug plate 103 conducts the heat away from the component to be protected and allows the heat to be dissipated through the rectilinear fins as the vertical air flow passes therebetween.

The fins such as the fin 101 extend vertically when the heat sink 58 is mounted to its operative component as shown in FIG. 26. The fins are generally equally spaced apart.

For a preferred operation, the heat sink 58 has certain critical dimensions for a preferred embodiment of the invention. In this regard, the heat sink 58 is generally in the shape of a block, which is generally rectangular in cross-section. For one preferred application, the overall dimensions of the heat sink include a width of between about 64.237 mm and about 68.580 mm, a length of between about 81.331 mm and about 95.606 mm, and a height of between about 24.765 mm and about 32.258 mm. The overall height dimension includes the height of the slug plate 103. The slug plate height is about 3.175 mm for a preferred application. The height of the fin is preferably between about 19.050 mm and about 26.543 mm, and the spacing between fins is preferably between about 2.311 mm and about 2.362 mm. The base 102 has a preferred thickness of about 2.540 mm.

In accordance with a preferred embodiment of the invention, it is important to have long fins as compared to the overall height of the heat sink. This provides for sufficient cooling air flow. Thus, there is no need for fans located at or near the heat sink. The air blowing through the blade passes vertically upwardly through the heat sink 58 and between the fins such as the fin 101 with little obstruction to the air flow.

In accordance with the preferred embodiments of the present invention, it has been found that the preferred ratio of the height of the fins such as the fin 101 to the height of the base portion such as the base portion 102 is greater than 7 and more preferably is between about 7.5 and about 10.45. These preferred ratios have proven to achieve the desired cooling effect when the heat sink is mounted with the fins extending vertically as indicated in FIG. 26.

The heat sink 58 is disposed vertically and is fastened in place by a series of fastening devices such as the fastening device 105 in the form of a bolt or screw. In this manner, the fins such as the fin 101 extends in a generally vertical disposition to interact with the vertical air flow.

Referring now to FIGS. 30, 31 and 32, there is shown another heat sink 107, which is generally similar to the heat sink 58, except for its means of attachment. The heat sink 107 includes a series of spaced-apart fins such as a fin 109 for facilitating the dissipation of heat. The heat sink 107 includes a base or slug 112 which is generally similar to the slug 101 and is preferably composed of a metallic material such as copper.

The heat sink 107 is adapted to be attached to an operative component 110 such as a microprocessor to be protected by a suitable attachment device such as a clip 113 or other attachment devices which engage a space 114 centrally disposed between groups of the fins.

While particular embodiments of the present invention have been disclosed, it is to be understood that various different modifications and combinations are possible and are contemplated within the true spirit and scope of the appended claims. There is no intention, therefore, of limitations to the exact abstract and disclosure herein presented.

What is claimed is:

1. A heat sink for an active component mounted on an upright support, comprising:
a base portion having a series of spaced aparat fins extending therefrom to provide a relatitvely large surface area to dissipate heat thereforem as substantially vertically flowing cooling air passes between the fins;
said base portion and said fins being composed of heat conducting material;
said base portion for mounting in a generally upright position with its foms extending in a generally upright position, and
the ratio of the height of the fins to the height of the base portion is greater than seven.

2. A heat sink according to claim 1, wherein said ratio is between about 7.5 and about 10.45.

3. A heat sink according to claim 1, further including a heat conducting slug plate overlying said base portion.

4. A heat sink according to claim 3, wherein said slug plate is composed of copper material.

5. A heat sink according to claim 4, wherein said base portion and said fins are composed of aluminum material.

6. A heat sink according to claim 4. Wherein said base portion and said fins are integral, and are extruded from aluminum material.

7. A heat sink according to claim 3, wherein said heat sink is generally in the share of a block, said block being generally rectangular in cross-section.

8. A heat sink according to claim 7, wherein said heat sink has an overall width of between about 64.237 mm and about 68.580 mm, an overall length of between about 81.331 mm and about 95.606 mm, and an overall height of between about 24.765 mm and about 32.258 mm.

9. A heat sink according to claim 8, wherein said overall height includes the height of said slug plate, said height of said slug plate being about 3.175 mm.

10. A heat sink according to claim 7, wherein the length of the fin is preferably between about 19.05 mm and about 26.543 mm.

11. A heat sink according to claim 10, wherein the height of the base portion is about 2.540 mm.

12. A heat sink according to claim 11, wherein the spacing between said fins is about 2.311 mm and about 2.362 mm.

13. A method of utilizing a heat sink for helping cool an active component, comprising:
mounting a support in a generally upright manner;
mounting the active component on one side of the support;
mounting the heat sink on the active component in a generally upright manner, the heat sink having spaced-apart fins extending from a base portion in generally upright manner; and
causing air to flow in said generally upright manner past the fins of the heat sink.

14. A method according to claim 13, further including interposing a slug plate between the base portion and the active component to be cooled.
